(19) United States
(12) Patent Application Publication
(10) Pub. No.: US 2020/0146190 A1
(43) Pub. Date: May 7, 2020

(54) ELECTRONIC APPARATUS

(71) Applicant: SAMSUNG ELECTRONICS CO., LTD., Suwon-si (KR)

(72) Inventors: Dong Hyun SEO, Suwon-si (KR); Byung Jin LEE, Suwon-si (KR)

(73) Assignee: SAMSUNG ELECTRONICS CO., LTD., Suwon-si (KR)

(21) Appl. No.: 16/670,544

(22) Filed: Oct. 31, 2019

(30) Foreign Application Priority Data
Nov. 1, 2018 (KR) 10-2018-0133080

(51) Int. Cl. H05K 7/20; H01L 23/367; G06F 1/20

(52) U.S. Cl. CPC H05K 7/20954; G06F 1/20; H05K 7/20418; H01L 23/367

(57) ABSTRACT

An electronic apparatus includes a printed circuit board (PCB); a circuit element mounted on the PCB; a heat sink contacting the circuit element and configured to receive heat generated by the circuit element; a bottom chassis configured to support the PCB and the heat sink; and a coupling member connecting the heat sink and the bottom chassis and configured to transfer heat received from the heat sink to the bottom chassis.

### CROSS-REFERENCE TO RELATED APPLICATION(S)

This application is based on and claims priority under 35 U.S.C. § 119 to Korean Patent Application No. 10-2018-0133080, filed on Nov. 1, 2018, in the Korean Intellectual Property Office, the disclosure of which is incorporated by reference herein in its entirety.

### BACKGROUND

### 1. Field

The disclosure relates to an electronic apparatus having an improved heat dissipation structure for a circuit element.

### 2. Description of Related Art

An electronic apparatus may include circuit elements, a printed circuit board (PCB) on which the circuit elements are mounted, and a bottom chassis provided to support the PCB.

The circuit element may generate high temperature heat resulting from high frequency operation when driven. Accordingly, the electronic apparatus may require various heat dissipation structures for dissipating heat generated in the circuit elements.

The heat dissipation structure may include a heat dissipation structure that dissipates heat by conducting heat from the circuit element to the PCB. However, the conduction-based heat dissipation structure may increase the temperature of other circuit elements adjacent to the circuit element mounted on the PCB, resulting in performance degradation and life-shortening of the other circuit elements.

The heat dissipation structure may include a heat dissipation structure that dissipates heat using a heat sink attached to the circuit element. The heat dissipation structure using the heat sink achieves the heat dissipation through an air flow and therefore has poor efficiency in heat dissipation. In addition, as the heat sink attached to the circuit element vibrates together with the circuit element, noise may occur.

On the other hand, in order to couple the PCB to the bottom chassis, a separate fastening member may be required, and the bottom chassis coupled to the PCB by the separate fastening member does not greatly contribute to heat dissipation of the circuit elements.

Examples of the electronic apparatus including the heat dissipation structure may include a display device. The display device is a device that displays visual and stereoscopic image information.

The display device may include not only a television (TV), a monitor, but also a portable multimedia device, such as a digital broadcasting terminal, a personal digital assistant (PDA), a portable multimedia player (PMP), a portable communication device, such as a smartphone or a wearable device, and other various forms of devices.

### SUMMARY

Provided is an electronic apparatus having an improved reliability in heat dissipation of circuit elements.

Also provided an electronic apparatus to fix a heat sink to a bottom chassis together with a PCB.

Also provided is an electronic apparatus in which a PCB and a bottom chassis contribute to heat dissipation of circuit elements.

Additional aspects will be set forth in part in the description which follows and, in part, will be apparent from the description, or may be learned by practice of the presented embodiments.

In accordance with an aspect of the disclosure, there is provided an electronic apparatus including: a printed circuit board (PCB); a circuit element mounted on the PCB; a heat sink contacting the circuit element and configured to receive heat generated by the circuit element; a bottom chassis configured to support the PCB and the heat sink; and a coupling member connecting the heat sink and the bottom chassis and configured to transfer heat received from the heat sink to the bottom chassis.

The coupling member may be integrally formed with the heat sink and protrudes from a mounting portion of the bottom chassis on which the PCB is mounted.

The coupling member may pass through the heat sink to couple the heat sink to the bottom chassis.

The coupling member may pass through the PCB, and the PCB is arranged between the heat sink and the bottom chassis.

The heat sink may include a sink hole through which the coupling member passes.

The PCB may include a substrate hole through which the coupling member passes.

The sink hole and the substrate hole may be coaxially arranged with respect to the coupling member.

The coupling member may include a conductive material.

The coupling member may include a body portion supporting the PCB and the heat sink, and a head portion extending from the body portion to latch onto the heat sink.

The head portion may have a cross section that is larger than an area of the sink hole.

The head portion may include an elastic material such that the head portion passes through the sink hole.

The head portion may include a head body portion extending from the body portion and a catching portion extending from the head body portion to engage the heat sink.

The catching portion may be arranged to surround the body portion while being spaced apart from the body portion.

The PCB may include a ground layer for dissipating heat received from the coupling member.

The coupling member may couple the heat sink, the PCB, and the bottom chassis such that the heat generated by the circuit element is transferred to the heat sink, the PCB and the bottom chassis through the coupling member.

According to an aspect of the disclosure, there is provided an electronic apparatus including: a printed circuit board PCB; a circuit element mounted on the PCB; a heat sink arranged adjacent to the PCB and configured to receive heat generated by the circuit element and dissipate the heat; a bottom chassis on which the PCB and the heat sink are supported; and a coupling member configured to couple the heat sink, the PCB, and the bottom chassis such that the heat generated by the circuit element is transferred to the heat sink, the PCB and the bottom chassis.

The coupling member may be integrally formed with the heat sink.

The bottom chassis may include a chassis hole through which the coupling member passes.

According to an aspect of the disclosure, there is provided an electronic apparatus including: a PCB; a circuit element mounted on the PCB; a heat sink contacting the circuit element and configured to dissipate heat generated by the circuit element; a bottom chassis configured to support the heat sink; and a coupling member configured to transfer heat received from the heat sink, wherein the coupling member includes a body portion that passes through the PCB and the heat sink, and a head portion extending from the body portion engaging the heat sink.

The head portion may include a catching portion that is spaced apart from the body portion and includes an elastic material, and the catching portion may engage the heat sink to couple the heat sink to the bottom chassis.

### BRIEF DESCRIPTION OF THE DRAWINGS

The above and/or other aspects, features, and advantages of certain embodiments of the present disclosure will be more apparent from the following description taken in conjunction with the accompanying drawings, in which:

FIG. 1 is a perspective view illustrating an electronic apparatus according to an embodiment;

FIG. 2 is an exploded view illustrating an electronic apparatus according to an embodiment;

FIG. 3 is a view illustrating an example of a heat sink and a PCB coupled to a bottom chassis according to an embodiment;

FIG. 4 is an enlarged view showing a portion A of FIG. 3 according to an embodiment;

FIG. 5 is a view illustrating an example of a heat sink and a PCB separated from a bottom chassis according to an embodiment;

FIG. 6 is a cross-sectional view taken along line B-B of FIG. 4 according to an embodiment;

FIG. 7 is another cross-sectional view illustrating a heat dissipation path of a circuit element shown in FIG. 6, according to an embodiment; and

FIG. 8 is a cross-sectional view illustrating an example of a heat sink, a PCB, and a bottom chassis coupled to each other according to an embodiment.

### DETAILED DESCRIPTION

Embodiments described and illustrated in the disclosure are only examples, and various modifications thereof may also fall within the scope of the disclosure.

Throughout the drawings, like reference numerals may refer to like parts or components.

The terminology used herein is for describing embodiments only and is not intended to limit the scope of the embodiments. It is to be understood that the singular forms “a,” “an,” and “the” may include plural references unless the context clearly dictates otherwise.

It may be understood that the terms “include”, “comprise” and/or “have” may specify the presence of stated features, integers, steps, operations, elements, and/or components, but do not preclude the presence or addition of one or more other features, integers, steps, operations, elements, components, and/or groups thereof.

The terms including ordinal numbers like “first” and “second” may be used to explain various components regardless of any order and/or degree of importance, and the components may not be limited by the terms. In addition, the terms may be used to distinguish one component from another.

Thus, a first element, component, region, layer or section discussed herein may be termed a second element, component, region, layer or section without departing from the teachings of the disclosure. The disclosure shall be understood as to include any and all combinations of one or more of the associated listed items when the items are described by using the conjunctive term “˜ and/or ˜,” or the like.

The terms “front”, “rear”, “upper”, “lower”, “top”, and “bottom” may be defined with respect to the drawings, but the terms may not restrict the shape and position of the respective components.

Hereinafter, embodiments will be described in detail with reference to the accompanying drawings.

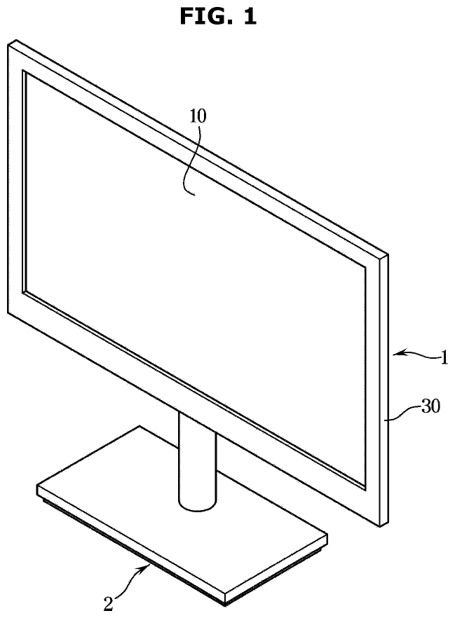

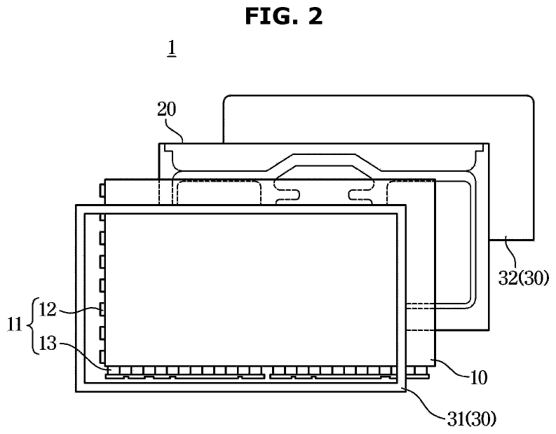

FIG. 1 is a perspective view illustrating an electronic apparatus according to an embodiment. FIG. 2 is an exploded view illustrating an electronic apparatus according to an embodiment. Referring to FIGS. 1 and 2, an electronic apparatus 1 may include a display device, such as a television, a monitor, and a mobile communication terminal, that displays an image. However, the electronic apparatus 1 is not limited thereto.

The electronic apparatus 1 may display an image and output sound. Here, the sound may be output through an external device provided at an outside of the electronic apparatus 1.

The electronic apparatus 1 may be supported by a stand 2 mounted at the bottom of the electronic apparatus 1, or may be installed on a wall by a separate bracket or the like.

The electronic apparatus 1 may include a display panel 10, a bottom chassis 20, and a housing 30.

The display panel 10 may include an image driver 11 provided to drive an image. The image driver 11 may include a first image driver 12 for driving an X electrode and a second image driver 13 for driving an Y electrode.

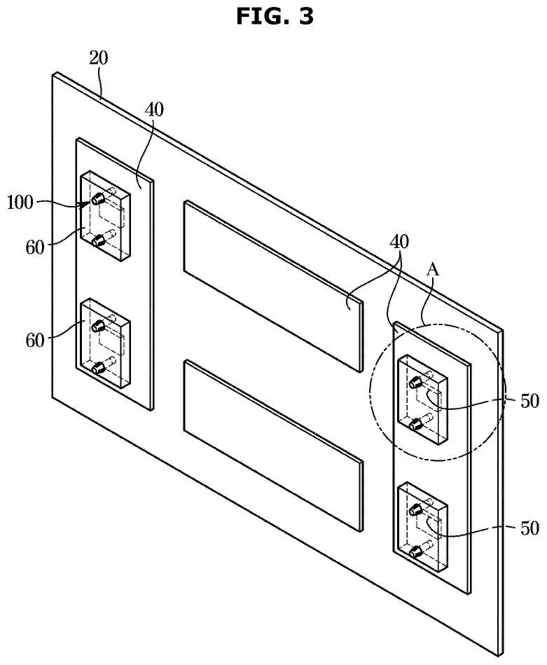

Here, the X electrode may include a source electrode and the Y electrode may include a gate electrode. The first image driver 12 and the second image driver 13 may be connected to a circuit element 50 in FIG. 3 mounted on a printed circuit board (PCB) 40 in FIG. 3.

The bottom chassis 20 is a panel that connects various components required for image display and sound output, and on the bottom chassis 20, various PCBs 40 and input/output devices may be mounted.

The bottom chassis 20 may be disposed at a rear side of the display panel 10. The bottom chassis 20 may be formed of a metal having excellent heat dissipation characteristics and strength. The bottom chassis 20 may be formed of a conductive material.

The heat dissipation of the bottom chassis 20 will be described below.

The housing 30 may include a bezel 31 and a housing cover 32. The bezel 31 may support the display panel 10. The bezel 31 may be fixed to the display panel 10 and may be detachably coupled to the housing cover 32.

The bezel 31 may form an accommodation space together with the housing cover 32 coupled thereto, and the display panel 10 and the bottom chassis 20 may be arranged in the accommodation space.

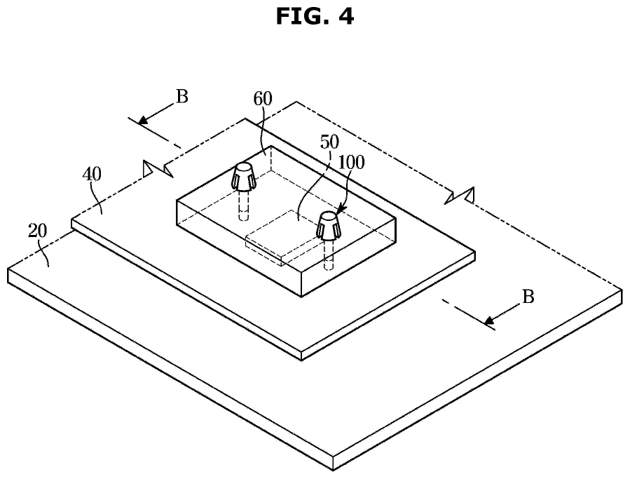

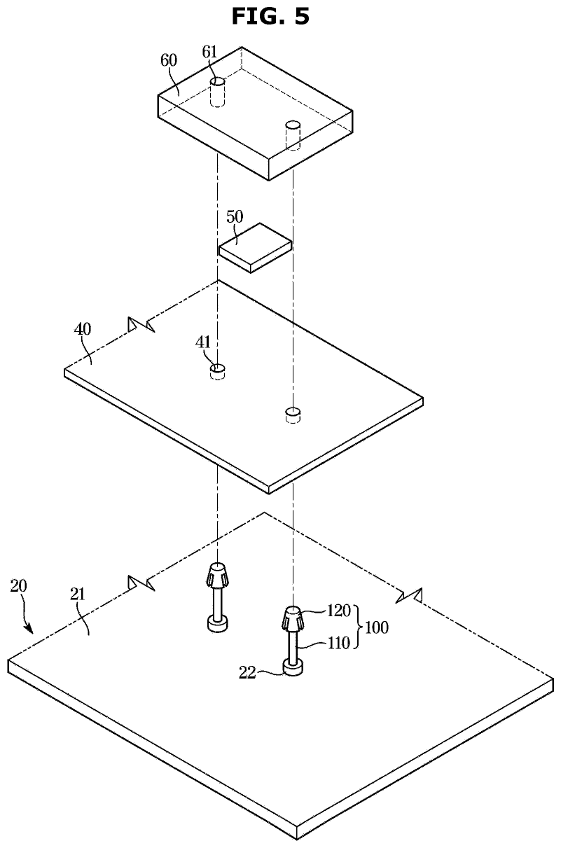

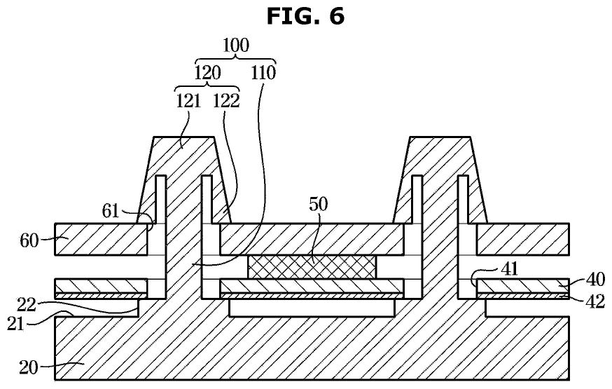

FIG. 3 is a view showing an example of a heat sink and a PCB board coupled to a bottom chassis. FIG. 4 is an enlarged view showing a portion A of FIG. 3. FIG. 5 is a view showing an example of a heat sink and a PCB separated from a bottom chassis. FIG. 6 is a cross-sectional view taken along line B-B of FIG. 4.

Referring to FIGS. 3, 4, 5, and 6, the electronic apparatus 1 may include the PCB 40 on which the circuit element 50 for driving the display panel 10 is mounted and the heat sink 60 coming into contact with the circuit element 50 to dissipate heat generated by the circuit element 50. For example, the heat sink 60 may be in contact with one side of the circuit element 50.

The heat sink 60 may be disposed between the display panel 10 and the PCB 40. The heat sink 60 may be disposed in the vicinity of the PCB 40.

The PCB 40 may be disposed at an upper side of the bottom chassis 20, and the circuit element 50 may be disposed at an upper side of the PCB 40. The heat sink 60 may be disposed at an upper side of the circuit element 50. However, the arrangement of the PCB 40, the circuit element 50, and the heat sink 60 is not limited thereto.

The bottom chassis 20 may include a mounting portion 21 on which the PCB 40 is mounted and a boss 22 protruding from the mounting portion 21. The boss 22 may support the PCB 40.

Although the boss 22 is illustrated as having a cylindrical shape in FIG. 4, the shape is not limited thereto. The boss 22 may include various shapes and structures as long as it can stably support the PCB 40 on the bottom chassis 20.

The heat sink 60 may be attached to the circuit element 50, and may be configured to dissipate heat generated in the circuit element 50 during driving of the display panel 10, that is, at a time of selecting a corresponding electrode according to a reset period, an address period, or a sustain period, and applying a pulse waveform suitable for the period.

The circuit element 50 may include a metal board in parallel with the PCB 40 and a wiring pattern having an insulating layer interposed in the metal board and on which a plurality of devices are formed. In addition, the circuit element 50 may be covered with a resin.

The heat sink 60 may include a base coming into contact with the circuit element 50 and a plurality of heat dissipation fins protruding vertically from the base and radiating heat through convection.

The heat sink 60 may be composed of a device that absorbs heat generated by an electrical component, such as the circuit element 50, and dissipates the heat to prevent overheating of the electrical component, and may prevent damage due to overheating of peripheral components as well as the electrical component itself.

The heat sink 60 may be formed of a heat conductive material, such as metal. In order to protect the heat sink 60, the bottom chassis 20 may be provided to restrict the movement of the heat sink 60, which may occur in the shipment, delivery, or the like of the electronic apparatus 1.

The heat sink 60 may have an area larger than that of the circuit element 50. The PCB 40 may have an area larger than that of the heat sink 60. The bottom chassis 20 may have an area larger than that of the PCB 40. However, the areas of the heat sink 60, the circuit element 50, and the PCB 40 are not limited thereto.

The electronic apparatus 1 may include a coupling member 100 connecting the heat sink 60, the PCB 40, and the bottom chassis 20 such that the heat generated by the circuit element 50 and transferred to the heat sink 60 is transferred to the PCB 40 and to the bottom chassis 20, and then to be discharged to the outside of the display device.

The coupling member 100 may be integrally formed with the bottom chassis 20. The coupling member 100 may include a conductive material. The bottom chassis 20 including the coupling member 100 may also include a conductive material.

The PCB 40 and the heat sink 60 may be supported by the bottom chassis 20.

The coupling member 100 may fix the heat sink 60 to the bottom chassis 20 while also fixing the PCB 40 to the bottom chassis 20, thereby obviating the need for installing a plurality of fixing members on the edge of the PCB to fix the PCB 40 to the bottom chassis 20.

However, the disclosure is not limited thereto. For example, in order to further securely fix the PCB 40 to the bottom chassis 20 and reinforce the grounding of the PCB 40, separate fixing members may be additionally installed on the edges of the PCB 40.

The electronic apparatus 1 fixes the heat sink 60 to the bottom chassis 20 using the coupling member 100, so that heat is transferred from the heat sink 60 to the bottom chassis 20 through a metal medium having excellent thermal conductivity, thereby improving heat dissipation characteristics of the heat sink 60.

Accordingly, the heat dissipation performance may be significantly increased under the same conditions, when compared to the structure that dissipates heat through an air flow.

The coupling member 100 may protrude from the mounting portion 21 of the bottom chassis 20 on which the PCB 40 is mounted. The coupling member 100 may protrude from the boss 22 of the bottom chassis 20 on which the PCB 40 is mounted.

The coupling member 100 may pass through the heat sink 60 such that the heat sink 60 is coupled to the bottom chassis 20. The coupling member 100 may pass through the PCB 40 such that the PCB 40 is arranged between the heat sink 60 and the bottom chassis 20 and is coupled to the bottom chassis 20.

The heat sink 60 may include a sink hole 61 through which the coupling member 100 passes. The PCB 40 may include a substrate hole 41 through which the coupling member 100 passes.

The heat sink 60 may have sides longer than those of the circuit element 50 such that the sink holes 61 are provided on the heat sink 60 without penetrating the circuit element 50. In other words, referring to FIG. 5, for example, a length between two sink holes 61 in the heat sink 60 is larger than a length of a side of the circuit element 50 such that the coupling members 100 passing through the sink holes 61 do not penetrate the circuit element 50. Similarly, the PCB 40 may have sides longer than those of the circuit element 50 such that the substrate holes 41 are provided in the PCB 40 without having the coupling members 100 penetrating the circuit element 50.

The coupling member 100 may be inserted into the sink hole 61 and is coupled to the bottom chassis 20, so that the heat sink 60 may be fixed to the bottom chassis 20. The coupling member 100 may be inserted into the substrate hole 41 and is coupled to the bottom chassis 20, so that the PCB 40 may be fixed to the bottom chassis 20.

That is, the coupling member 100 may pass through the sink hole 61 formed in the heat sink 60 and the substrate hole 41 formed in the PCB 40, thereby fixing the heat sink 60 and the PCB 40 to the bottom chassis 20.

The sink hole 61 and the substrate hole 41 may be coaxially arranged with respect to the coupling member 100.

The coupling member 100 may include a body portion 110 for supporting the PCB 40 and the heat sink 60, and a head portion 120 extending from the body portion 110 to engage or fasten the heat sink 60.

A part of the body portion 110 and the head portion 120 may be disposed above the heat sink 60 by passing through the substrate hole 41 of the PCB 40 and the sink hole 61 of the heat sink 60.

The areas of the substrate hole 41 and the sink hole 61 may be larger than the cross-sectional area of the body portion 110. The area of the substrate hole 41 and the area of the sink hole 61 may be the same. However, the disclosure is not limited thereto.

The cross-sectional area of the head portion 120 may be larger than the areas of the substrate hole 41 and the sink hole 61. Accordingly, the heat sink 60 may be prevented from being unfastened from the bottom chassis 20.

The head portion 120 may have elasticity such that the head portion 120 passes through the substrate hole 41 and the sink hole 61. Accordingly, the head portion 120 having a cross-sectional area larger than the areas of the substrate hole 41 and the sink hole 61 may pass through the substrate hole 41 and the sink hole 61 due to the elasticity.

Referring to FIG. 6, the head portion 120 may include a head body portion 121 extending from the body portion 110 and a catching portion 122 extending from the head body portion 121 such that the catching portion 122 engages one side of the heat sink 60. As such, the catching portion 122 fastens the heat sink 60 by latching onto the heat sink 60.

The catching portion 122 may extend from the head body portion 121 toward the heat sink 60. The catching portion 122 may be arranged between the head body portion 121 and the heat sink 60.

The catching portion 122 may be spaced apart from the body portion 110. The catching portion 122 may be arranged to surround the body portion 110. The catching portion 122 may be provided in a plurality of units thereof spaced apart from each other. However, the disclosure is not limited thereto.

The head body portion 121 may have a cross-sectional area smaller than the areas of the substrate hole 41 and the sink hole 61. The cross-sectional area of the catching portion 122 may be larger than the areas of the substrate hole 41 and the sink hole 61.

The catching portion 122 may have elasticity. The catching portion 122 may be moved a predetermined distance toward the body portion 110 by an external force. In a state in which the catching portion 122 is moved a predetermined distance toward the body portion 110 by an external force, the cross-sectional area of the catching portion 122 may be smaller than the areas of the substrate hole 41 and the sink hole 61.

When the external force is removed, the catching portion 122 may be moved a predetermined distance in a direction away from the body portion 110, returning to the original state.

Accordingly, in a state in which the catching portion 122 is moved a predetermined distance toward the body portion 110 by an external force, when the coupling member 100 passes through the substrate hole 41 and the sink hole 61, the catching portion 122 with the external force removed may be moved by a predetermined distance in a direction away from the body portion 110 and be latched onto the heat sink 60.

The coupling member 100 is illustrated as having a push-pin shape including the body portion 110 and the head portion 120 having elasticity, but the disclosure is not limited thereto.

The coupling member 100 may include various structures as long as it can couple the heat sink 60 and the PCB 40 to the bottom chassis 20, and transfer heat from the heat sink 60 to the PCB 40 and/or the bottom chassis 20.

The PCB 40 may include a ground layer 42 that may receive heat from the coupling member 100 and discharge the received heat. The ground layer 42 may constitute one layer of the PCB 40. However, the disclosure is not limited thereto. The ground layer 42 may be formed with the substrate hole 41.

The coupling member 100 may be formed of a material having excellent thermal conductivity, and excellent electrical conductivity. The coupling member 100 having excellent electrical conductivity may additionally perform a grounding function for the PCB 40.

Accordingly, the coupling member 100 may prevent electromagnetic waves of the PCB 40 interfering with operations of the circuit element 50 or other components disposed in the electronic apparatus 1.

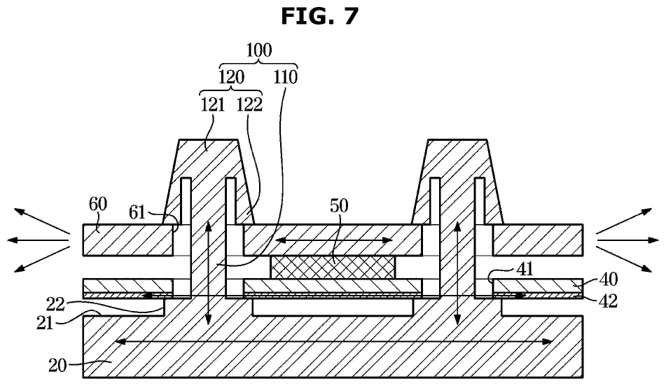

FIG. 7 is a cross-sectional view showing a heat dissipation path of a circuit element shown in FIG. 6. Referring to FIG. 7, the electronic apparatus 1 may allow heat generated by the circuit element 50 to be transferred not only to the heat sink 60, but also to the PCB 40 and the bottom chassis 20 through the heat sink 60, and then to be discharged.

Hereinafter, a heat dissipation process of the electronic apparatus 1 according an embodiment will be described in detail.

First, heat generated in the circuit element 50 in the process of driving the electronic apparatus 1 may be transferred to the heat sink 60 in contact with one side of the circuit element 50 such that the heat is primarily discharged into the air.

The electronic apparatus 1 may include a heat dissipation structure for dissipating heat using the PCB 40 and the bottom chassis 20 through the heat sink 60, in addition to the heat dissipation structure for dissipating heat into the air through the heat sink 60.

Heat generated by the circuit element 50 and transferred to the heat sink 60 is transferred from the heat sink 60 to the PCB 40 and the bottom chassis 20 through the coupling member 100 that couples the heat sink 60, the PCB 40, and the bottom chassis 20 together.

Heat is transferred from the heat sink 60 to the bottom chassis 20 through the coupling member 100, and heat dissipation may be additionally performed through the bottom chassis 20 composed of a conductive material.

Heat is transferred from the heat sink 60 to the PCB 40 through the coupling member 100, and heat dissipation may be additionally performed through the PCB 40 including the ground layer 42.

Accordingly, the electronic apparatus 1 may easily assemble the heat sink 60, the PCB 40, and the bottom chassis 20 through the coupling member 100, and since the heat generated by the circuit element 50 is discharged through the heat sink 60, the PCB 40, and the bottom chassis 20 via the coupling member 100, the heat dissipation efficiency is significantly increased.

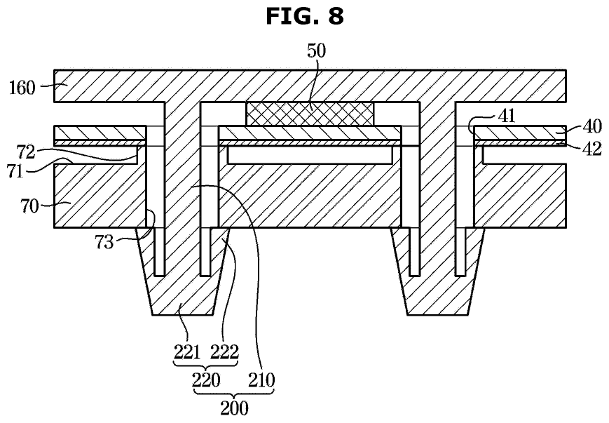

FIG. 8 is a cross-sectional view illustrating an example of a heat sink, a PCB, and a bottom chassis coupled to each other. Referring to FIG. 8, the coupling member 200 may be integrally formed with the heat sink 160.

Here, a heat sink 160 may come into contact with one side of the circuit element 50.

The PCB 40 may be disposed at an upper side of a bottom chassis 70, and the circuit element 50 may be disposed at an upper side of the PCB 40. The heat sink 160 may be disposed at an upper side of the circuit element 50. However, the disclosure is not limited thereto.

The bottom chassis 70 may include a mounting portion 71 on which the PCB 40 is mounted, and a boss 72 protruding from the mounting portion 71. The boss 72 may support the PCB 40.

A coupling member 200 may connect the heat sink 160, the PCB 40, and the bottom chassis 70 such that heat generated by the circuit element 50 is transferred to the heat sink 160, and to the PCB 40 and the bottom chassis 70, to be discharged to the outside.

The coupling member 200 may include a conductive material. The heat sink 160 including the coupling member 200 may include a conductive material. The PCB 40 and the heat sink 160 may be supported by the bottom chassis 70.

Since the heat sink 160 is fixed to the bottom chassis 70 using the coupling member 200, heat from the heat sink 160 is transferred to the bottom chassis 70 through a metal medium included in the coupling member 200, so that heat dissipation performance of the heat sink 160 may be improved.

The coupling member 200 may protrude from the heat sink 160. The coupling member 200 may protrude downward from the heat sink 160. The coupling member 200 may protrude from the heat sink 160 toward the PCB 40.

The coupling member 200 may pass through the bottom chassis 70 such that the heat sink 160 is coupled to the bottom chassis 70. The coupling member 200 may pass through the PCB 40 such that the PCB 40 is disposed between the heat sink 160 and the bottom chassis 70 and is coupled to the bottom chassis 70.

The bottom chassis 70 may include a chassis hole 73 through which the coupling member 200 passes. The PCB 40 may include a substrate hole 41 through which the coupling member 200 passes.

The bottom chassis 70 may have sides longer than sides of the circuit element 50 such that the chassis holes 73 are provided on the bottom chassis 70 without penetrating the circuit element 50. That is, for example, a length between two chassis holes 73 on the bottom chassis 70 is larger than a length of a side of the circuit element 50 such that the coupling members 200 passing through the chassis holes 73 do not penetrate the circuit element 50. Similarly, the PCB 40 may have sides longer than sides of the circuit element 50 such that the substrate holes 41 are be provided in the PCB 40 without having the coupling members 200 penetrating the circuit element 50.

The chassis hole 73 may be provided in the boss 72. However, the disclosure is not limited thereto.

As the coupling member 200 is inserted into the chassis hole 73 and is coupled to the bottom chassis 70, the heat sink 160 may be fixed to the bottom chassis 70. As the coupling member 200 is inserted into the substrate hole 41 and is coupled to the bottom chassis 70, the PCB 40 may be fixed to the bottom chassis 70.

That is, the coupling member 200 passes through the chassis hole 73 formed in the bottom chassis 70 and the substrate hole 41 formed in the PCB 40, thereby fixing the heat sink 160 and the PCB 40 to the bottom chassis 70.

The chassis hole 73 and the substrate hole 41 may be coaxially arranged with respect to the coupling member 200.

The coupling member 200 may include a body portion 210 passing through the PCB 40 and the bottom chassis 70, and a head portion 220 extending from the body portion 210 to be latched onto the bottom chassis 70.

A part of the body portion 210 and the head portion 220 may be disposed at a lower side of the bottom chassis 70 by passing through the substrate hole 41 of the PCB 40 and the chassis hole 73 of the bottom chassis 70.

The areas of the substrate hole 41 and the chassis hole 73 may be larger than the cross-sectional area of the body portion 210. The area of the substrate hole 41 and the area of the chassis hole 73 may be the same. However, the disclosure is not limited thereto.

The cross-sectional area of the head portion 220 may be larger than the areas of the substrate hole 41 and the chassis hole 73. Accordingly, the heat sink 160 may be prevented from being unfastened from the bottom chassis 70.

The head portion 220 may be elastic such that the head portion 220 passes through the substrate hole 41 and the chassis hole 73. Accordingly, the head portion 220 having a cross-sectional area larger than the areas of the substrate hole 41 and the chassis hole 73 may pass through the substrate hole 41 and the chassis hole 73 due to the elasticity.

The head portion 220 may include a head body portion 221 extending from the body portion 210 and a catching portion 222 extending from the head body portion 221 to be interfered with one side of the bottom chassis 70.

The catching portion 222 may extend from the head body portion 221 toward the bottom chassis 70. The catching portion 222 may be arranged between the head body portion 221 and the bottom chassis 70.

The catching portion 222 may be spaced apart from the body portion 210. The catching portion 222 may be disposed to surround the body portion 210. In addition, the catching portions 222 may be provided in a plurality of units thereof spaced apart from each other. However, the disclosure is not limited thereto.

The cross-sectional area of the head body portion 221 may be smaller than the areas of the substrate hole 41 and the chassis hole 73. The cross-sectional area of the catching portion 222 may be larger than the areas of the substrate hole 41 and the chassis hole 73.

The catching portion 222 may be elastic. The catching portion 222 may be moved a predetermined distance toward the body portion 210 by an external force. In a state in which the catching portion 222 is moved a predetermined distance toward the body portion 210 by an external force, the cross-sectional area of the catching portion 222 may be smaller than the areas of the substrate hole 41 and the chassis hole 73.

When the external force is removed, the catching portion 222 may be moved a predetermined distance in a direction away from the body portion 210, returning to its original state.

Accordingly, in a state in which the catching portion 222 is moved a predetermined distance toward the body portion 210 by an external force, when the coupling member 200 passes through the substrate hole 41 and the chassis hole 73, the catching portion 222 with the external force removed may be moved by a predetermined distance in a direction away from the body portion 210 and to be caught with the bottom chassis 70.

The PCB 40 may include a ground layer 42 that may receive heat from the coupling member 200 and discharge the received heat. The ground layer 42 may constitute one layer of the PCB 40. However, the disclosure is not limited thereto.

As described above, the heat sink may be fixed to the bottom chassis together with the PCB, so that the reliability and efficiency in the heat dissipation of circuit elements can be improved.

Since the PCB and the bottom chassis contribute to the heat dissipation of the circuit elements together with the heat sink, the heat dissipation path may be diversified.

Further, since the heat sink and the PCB are fixed to the bottom chassis, vibration and noise may be reduced, and the PCB may be easily coupled to the bottom chassis without a separate fastening member.

Although the disclosure has been described with reference to the embodiments herein, it should be understood by those skilled in the art that changes and modifications may be made without departing from the scope and sprit of the disclosure. In addition, the scope of the disclosure encompasses all modifications and equivalents that fall within the scope of the appended claims and will be construed as being included in the disclosure.

What is claimed is:

1. An electronic apparatus comprising:
a printed circuit board (PCB);
a circuit element mounted on the PCB;
a heat sink contacting the circuit element and configured to receive heat generated by the circuit element;
a bottom chassis configured to support the PCB and the heat sink; and
a coupling member connecting the heat sink and the bottom chassis, and configured to transfer heat received from the heat sink to the bottom chassis.

2. The electronic apparatus of claim 1, wherein the coupling member is integrally formed with the heat sink and protrudes from a mounting portion of the bottom chassis on which the PCB is mounted.

3. The electronic apparatus of claim 1, wherein the coupling member passes through the heat sink to couple the heat sink to the bottom chassis.

4. The electronic apparatus of claim 1, wherein the coupling member passes through the PCB, and the PCB is arranged between the heat sink and the bottom chassis.

5. The electronic apparatus of claim 1, wherein the heat sink comprises a sink hole through which the coupling member passes.

6. The electronic apparatus of claim 5, wherein the PCB comprises a substrate hole through which the coupling member passes.

7. The electronic apparatus of claim 6, wherein the sink hole and the substrate hole are coaxially arranged with respect to the coupling member.

8. The electronic apparatus of claim 1, wherein the coupling member comprises a conductive material.

9. The electronic apparatus of claim 5, wherein the coupling member comprises a body portion supporting the PCB and the heat sink, and a head portion extending from the body portion to engage the heat sink.

10. The electronic apparatus of claim 9, wherein the head portion has a cross section that is larger than an area of the sink hole.

11. The electronic apparatus of claim 10, wherein the head portion comprises an elastic material such that the head portion passes through the sink hole.

12. The electronic apparatus of claim 9, wherein the head portion comprises a head body portion extending from the body portion and a catching portion extending from the head body portion to engage the heat sink.

13. The electronic apparatus of claim 12, wherein the catching portion is arranged to surround the body portion while being spaced apart from the body portion.

14. The electronic apparatus of claim 1, wherein the PCB comprises a ground layer for dissipating heat received from the coupling member.

15. The electronic apparatus of claim 1, wherein the coupling member couples the heat sink, the PCB, and the bottom chassis such that the heat generated by the circuit element is transferred to the heat sink, the PCB and the bottom chassis through the coupling member.

16. An electronic apparatus comprising:
a printed circuit board (PCB);
a circuit element mounted on the PCB;
a heat sink arranged adjacent to the PCB and configured to receive heat generated by the circuit element and dissipate the heat;
a bottom chassis on which the PCB and the heat sink are supported; and
a coupling member configured to couple the heat sink, the PCB, and the bottom chassis such that the heat generated by the circuit element is transferred to the heat sink, the PCB and the bottom chassis.

17. The electronic apparatus of claim 16, wherein the coupling member is integrally formed with the heat sink.

18. The electronic apparatus of claim 16, wherein the bottom chassis comprises a chassis hole through which the coupling member passes.

19. An electronic apparatus comprising:
a printed circuit board (PCB);
a circuit element mounted on the PCB;
a heat sink contacting the circuit element and configured to dissipate heat generated by the circuit element;
a bottom chassis configured to support the heat sink; and
a coupling member configured to transfer heat received from the heat sink,
wherein the coupling member comprises a body portion that passes through the PCB and the heat sink, and a head portion extending from the body portion engaging the heat sink.

20. The electronic apparatus of claim 19, wherein the head portion comprises a catching portion that is spaced apart from the body portion and comprises an elastic material, and
wherein the catching portion engages the heat sink to couple the heat sink to the bottom chassis.
